(19) United States
(12) Patent Application Publication
(10) Pub. No.: US 2003/0030879 A1
(43) Pub. Date: Feb. 13, 2003

(54) Deposition system design for arrayed wave-guide grating

(76) Inventors: Ga-Lane Chen, Fremont, CA (US); Charles Leu, Fremont, CA (US); Yi-Ting Yao, Pleasanto, CA (US)

Correspondence Address: WEI TE CHUNG, FOXCONN INTERNATIONAL, INC., 1650 MEMOREX DRIVE, SANTA CLARA, CA, 95050, US

(21) Appl. No.: 09/927,626

(22) Filed: Aug. 9, 2001

(51) Int. Cl. C23C 14/32; G02F 1/00; G02B 26/00

(52) U.S. Cl. 359/237; 204/298.04; 204/192.11

(57) ABSTRACT

This invention provides a new AWG deposition system to fabricate a multilayers AWG. In order to manufacture high quality films and reduce the pollution of chemicals, super high density plasma technology is applied to this system because the traditional processes such as MOCVD, PECVD, etc. use toxic chemicals to produce pollution and cause environment problem. The new design also provides a flexible ion sources, targets, power supplies, and mass flow rate controllers which numbers depend on the requirements of the system.

### BACKGROUND OF THE INVENTION

1. Field of The Invention

The present invention relates to a new arrayed wave-guide grating deposition system, which uses ion beam sputtered or plated with super high density plasma (SHDP) to fabricate AWG (Arrayed Wave Guide) by four steps without traditional chemical environmental pollutions.

2. The PriorArt

The conventional AWG device was fabricated with thermal oxidation, metal organic chemical vapor deposition (MOCVD), and plasma enhanced chemical vapor deposition (PECVD). Both of MOCVD and PECVD are chemical methods, which require complicated facility and waste gas treatment in the factory.

The conventional manufacturing processes have four steps, which include four thick film deposition steps with one mask process. First, the thick “thermal oxide SiO₂ with thickness at 15 μm was deposited on the silicon or SiO₂ substrates. To grow 15 μm thermal oxide SiO₂ may take three weeks long. Then, plasma enhanced CVD was used to deposit “core” layer. The core layer material is GeO₂-doped SiO₂ by MOCVD or PECVD or flame hydrolysis deposition (FHD). The core is isolated with SiO₂+P₂O₅+B₂O₃, which has different refractive index from the core layer material. PECVD or MOCVD was used as the chemical vapor deposition for core layer. The overcoat layer is SiO₂ with thickness 15 to 20 μm. PECVD was used as the deposition tool for this thick overcoat layer. Understandably, the conventional chemical vapor deposition method wastes time and results in pollution. Thus, an object of the invention is to provide an efficiently manufactured high quality AWG device without pollution.

### SUMMARY OF THE INVENTION

The physical vapor deposition such as ion beam sputter deposition or ion plating deposition by super high density plasma (SHDP) process is used to substitute the conventional chemical vapor deposition process such as MOCVD and PECVD to fabricate better optical and mechanical properties films for AWG on a silicon substrate without environmental pollutions.

The invented AWG layer structure has four process steps at least, which include multi thick film deposition steps with one mask process. The first layer is ion beam sputtered or ion-plated 15 μm SiO₂ film instead of thermal oxide SiO₂ deposition. Then, ion beam sputtering or ion plating is designed to form GeO₂-doped SiO₂ film as the “core” layer. With the semiconductor masking steps and reactive ion etching (RIE) process, the core layer material GeO₂-doped SiO₂ can be formed to create different refractive index from clay layer. The spacing between each core is about 2 μm. The width of core is 4 μm. The height of core is 4 to 8 μm. The core is isolated with SiO₂+P₂O₅+B₂O₃ material, which has different refractive index from the core layer material. Ion beam sputtering or ion plating was used for deposition instead of PECVD or MOCVD process. The overcoat layer is SiO₂ with thickness 15 to 20 μm. Ion beam sputtering or ion plating is designed for this thick overcoat deposition.

The overall processes without any PECVD process in the design to avoid poison/toxic gas for operation. The new design creates clean as well as high density plasma for AWG device. The RF power supply at 13.6 MHZ combined with ion source for sputtering targets and substrates has created super high density plasma in the new system. The new AWG device provides advantages on optical alignment for DWDM packaging. The AWG/DWDM can reach the milestones for future optical communication for 100 GHz/32 channels, 50 GHz/64 channels, to 25 GHz/128 channels.

### BRIEF DESCRIPTION OF THE DRAWINGS

FIG. 1 is the conventional AWG layer design fabricated by MOCVD, or PECVD, or FHD processes;

FIG. 2 is the new AWG layer design fabricated by SHDP process, which is a kind of physical vapor deposition process.

FIG. 3 is the new AWG deposition system, which comprises of RF power supplies, ion sources, substrates, shutters, mass flow rate controllers, and high vacuum pump in the high vacuum chamber.

### DETAIL DESCRIPTION OF THE PREFERRED EMBODIMENT

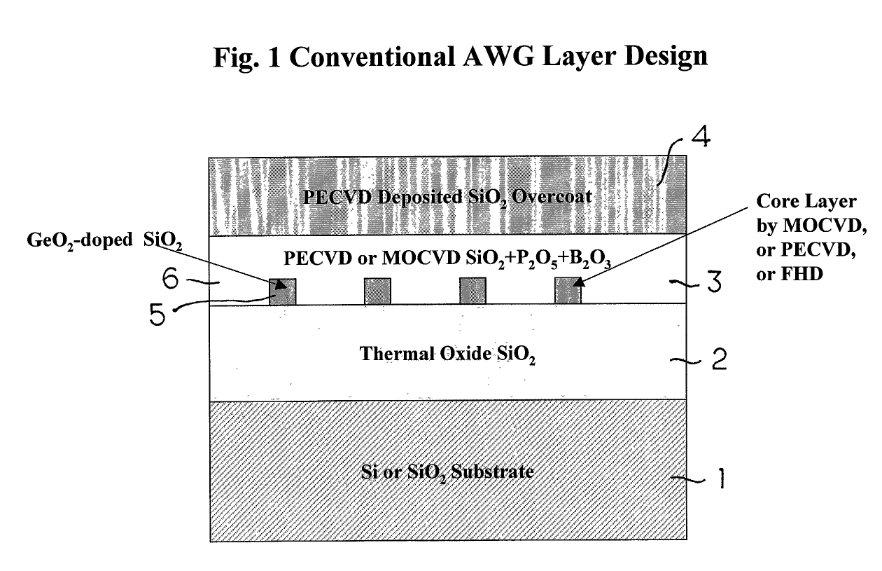

Referring to FIG. 1, the conventional AWG layer design comprises of four layers at least, Si or SiO₂ substrate 1, thermal oxide SiO₂ 2, core layer 3, and PECVD deposited SiO₂ overcoat 4.

The thermal oxide SiO₂ 2 is deposited on the Si or SiO₂ substrate 1 with 15 μm thickness. The core layer 3 compromises two materials, GeO₂doped SiO₂ 5 and SiO₂+P₂O₅+B₂O₃ 6. Both are deposited on thermal oxide SiO₂ 2 layer by MOCVD, or PECVD, or FHD processes. In the core layer 3, the GeO₂-doped SiO₂ 5 is isolated by SiO₂+P₂O₅+B₂O₃ 6. The overcoat layer 4 is SiO₂ deposited on the core layer 3 with 15 to 20 μm thickness by PECVD process.

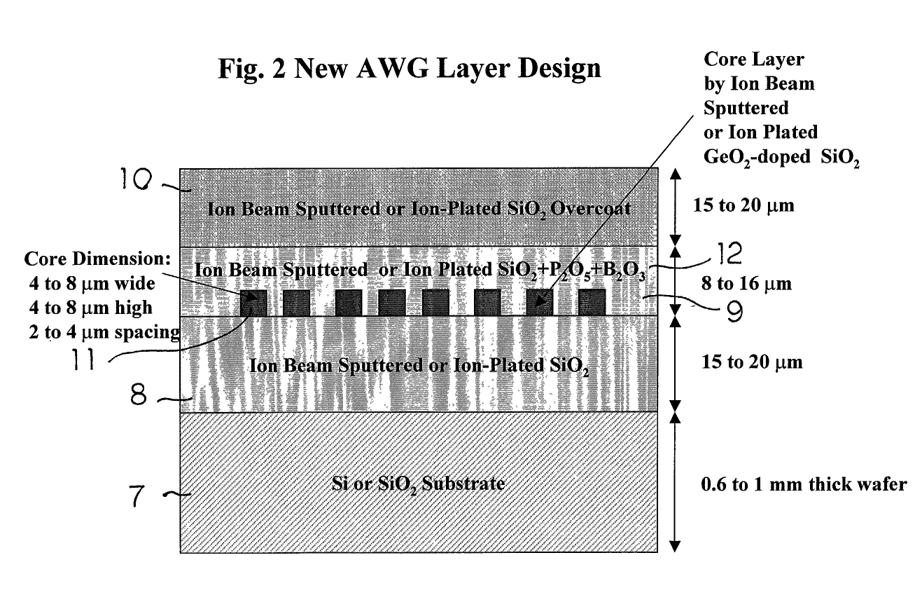

Referring to FIG. 2, the new AWG layer design comprises of four layers, Si or SiO₂ substrate 7, ion beam sputtered or ion plated SiO₂ 8, core layer 9, and ion beam sputtered or ion plated SiO₂ overcoat 10.

The Si or SiO₂ substrate 7 is 0.6 to 1mm thickness. The ion beam sputtered or ion plated SiO₂ 8 is deposited on the Si or SiO₂ substrate 7 with 15 to 20 μm thickness. The core layer 9 compromises two materials, GeO₂doped SiO₂ 11 and SiO₂+P₂O₅+B₂O₃ 12. Both are deposited on the ion beam sputtered or ion plated SiO₂ 8 layer by ion beam sputtered or ion plated processes. The dimensions of GeO₂-doped SiO₂ 11 are 4 to 8 μm wide, 4 to 8 μm high, and 2 to 4 μm spacing. In the core layer 9, the GeO₂-doped SiO₂ 11 is isolated by SiO₂+P₂O₅+B₂O₃ 12. The thickness of the core layer 9 is 8 to 16 μm. The overcoat layer 10 is SiO₂ deposited on the core layer 9 with 15 to 20 μm thickness by ion beam sputtered or ion plated process.

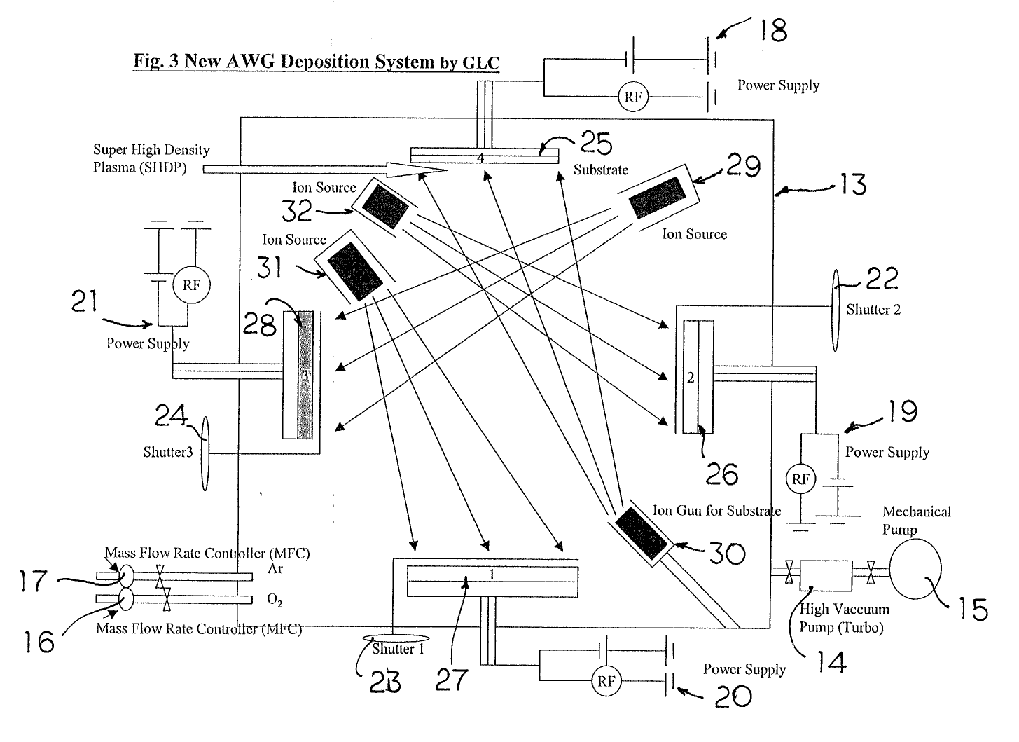

Referring to FIG. 3, the new AWG deposition system comprises of a vacuum chamber 13, a high vacuum pump 14, a mechanical pump 15, a mass flow rate controller for oxygen 16, a mass flow rate controller for argon 17, four RF power supply 18, 19, 20, 21, three shutters 22, 23, 24, four Si or SiO₂ substrates 25, 26, 27, 28, and four ion sources 29, 30, 31, 32.

The function of the mechanical pump 15 connected to the high vacuum pump 14 is to let the gas density to reduce to the 10⁻³/cm³ in the vacuum chamber 13. The high vacuum pump 14 connected to the vacuum chamber 13 is to reduce the gas density in the vacuum chamber to 10⁻⁷/cm³. The mass flow controller for oxygen 16 and the mass flow controller for argon 17 are connected to the vacuum chamber 13 to keep the densities of oxygen and argon in the vacuum chamber 13.

The RF power supply 18 provides electricity for the substrate 25, which the AWG films will grow on. The material of substrate 25 is Si or SiO₂. The ion sources 30 is served for the substrate 25 to control the quality of the film on the substrate 25. The RF power supply 19 provides electricity for the target 26 which the film material such as SiO₂ or GeO₂-doped SiO₂, or SiO₂+P₂O₅+B₂O₃ is placed on. The ion sources 32 is served for the substrate 26 to bombard the film on the substrate 26. The shutter 22 is to cover the target 26 to stop the ion source 32 to bombard the film material on target 26. The RF power supply 20 provides electricity for the target 27 which the film material such as SiO₂ or GeO₂-doped SiO₂, or SiO₂+P₂O₅+B₂O₃ is placed on. The ion sources 31 is served for the substrate 27 to bombard the film on the target 27. The shutter 23 is to cover the target 27 to stop the ion source 31 to bomb the film material on target 27. The RF power supply 21 provides electricity for the target 28 which the film material such as SiO₂ or GeO₂-doped SiO₂, or SiO₂+P₂O₅+B₂O₃ is placed on. The ion sources 29 is served for the target 28 to bombard the film on the substrate 28. The shutter 24 is to cover the target 28 to stop the ion source 29 to bombard the film material on target 28.

There are only four sets of ion source, target, power supply, and shutter shown in FIG. 3. In the practice, it could be increased to eight sets.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A system for making an AWG device comprising:
a chamber;
means for making super high vacuum in said chamber;
multiple ion sources provided around a periphery of and in said chamber; and
multiple targets disposed in said chamber around said periphery and opposite to the corresponding ion sources, respectively; wherein
the system creates a clean as well as super high density plasmas deposition structure for making the AWG device.

2. The system as defined in claim 1, wherein some of the targets are provided with shutters aside so as to isolate the undesired ions generated by the ion sources other than the ones exactly respectively opposite to said some of the targets.

3. The system as defined in claim 1, wherein gases O₂ and Ar are injected into the chamber.

4. The system as defined in claim 1, wherein the number of said targets correspond to layers of finally finished AWG device.

5. The system as defined in claim 1, wherein the one target positioned on a top portion of the chamber is accompanied with no shutter.

6. The system as defined in claim 1, wherein regularly only one set of targetion source is working at one time.

7. The system as defined in claim 1, wherein said means reduces an air density of the chamber to 10⁻⁷/cm³.

8. A method of making an AWG device, the steps comprising:
applying SiO₂ film on a substrate with an ion beam sputtered or ion-plated procedure;
applying GeO₂-doped SiO₂ film upon said SiO₂ film with the ion beam sputtered or ion-plated procedure wherein via masking processes and reactive ion etching process, dividing said GeO₂-doped SiO₂ film into several spaced pieces; and applying SiO₂+P₂O_{5+B}₂O₃ film upon said GeO₂-doped SiO₂ film and isolating said GeO₂-doped SiO₂ film with the ion beam sputtered or ion-plated procedure; and
applying SiO₂ overcoat film on a substrate with the ion beam sputtered or ion-plated procedure.

9. The method as defined in claim 8, further providing a physical vapor deposition system with a plurality of ion sources and a plurality of corresponding targets opposite to the corresponding ion source, around a periphery of a chamber which is controlled by means for super high vacuum for implementing said ion beam sputtered or ion-plated procedure.

10. The method as defined in claim 9, wherein said substrate is disposed upon one of the targets;

11. The method as defined in claim 9, wherein some of said targets are provided with corresponding shutters each for preventing the corresponding target from being coated with the undesired ionized material which is ejected from other ion sources other than the one opposite to the corresponding target.

12. The method as defined in claim 11, wherein each of the shutters is closed when the ion sources, other than the opposite one, are running.

13. The AWG device made by the method defined in claim 8.

14. An AWG device comprising:
a substrate of Si or SiO₂;
an ion beam sputtered or ion-plated SiO₂ layer applied upon said substrate;
an ion beam sputtered or ion plated SiO₂+P₂O₅+B₂O₃ layer with spaced GeO₂-doped SiO₂ film applied upon the SiO₂ layer; and
an ion beam sputtered or ion plated SiO₂+P₂O₅+B₂O₃ layer with spaced GeO₂-doped SiO₂ film applied upon the SiO₂ layer; and
an ion beam sputtered or ion-plated SiO₂ overcoat layer applied upon said SiO₂+P₂O₅+B₂O₃ layer.

15. The AWG device as defined in claim 14, wherein each of said GeO₂-doped SiO₂ film is of 4 to 8 μm wide, 4 to 8 μm wide, and 2 to 8 μm wide.

16. The AWG device as defined in claim 14, wherein the substrate defines 0.6 to 1 mm thick wafer, the SiO₂ layer above said substrate defines 15 to 20 μm, the SiO₂+P₂O₅+B₂O₃ layer defines 8 to 16 μm, and the SiO₂ overcoat layer defines 15 to 20 μm.

17. The method as defined in claim 10, wherein the target which said substrate located at, is positioned on a top portion of the chamber for avoid gravity fluence.
